(19) United States
(12) Patent Application Publication
(10) Pub. No.: US 2009/0008777 A1
(43) Pub. Date: Jan. 8, 2009

(54) INTER-CONNECTING STRUCTURE FOR SEMICONDUCTOR DEVICE PACKAGE AND METHOD OF THE SAME

(75) Inventors: Diann-Fang Lin, Hukou Township (TW); Wen-Kun Yang, Hsin-Chu City (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/773,993

(22) Filed: Jul. 6, 2007

(51) Int. Cl. H01L 29/40; H01L 21/4763; H01L 23/48

(52) U.S. Cl. 257/738; 257/774; 438/648; 438/650; 257/E29.112; 257/E23.011; 257/E21.495

(57) ABSTRACT

An interconnecting structure for a semiconductor die assembly, comprising: a substrate with pre-formed wiring circuit formed therein; a die having contact pads on an active surface; an adhesive material formed over the substrate to adhere the die over the substrate, wherein the substrate includes a via through the substrate and the adhesive material; and conductive material refilled into the via to couple the contact pads of the die to the wiring circuit of the substrate.

### FIELD OF THE INVENTION

This invention relates to a semiconductor package, and more particularly to an inter-connecting structure for a package.

### DESCRIPTION OF THE PRIOR ART

High performance integrated circuit (IC) packages are well known in the art. Improvements in IC packages are driven by industry demands for increased thermal and electrical performance and decreased size and cost of manufacture. In the field of semiconductor devices, the device density is increased and the device dimension is reduced, continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor become more complicated, the traditional package technique, for example lead frame package, flex package, rigid package technique, can't meet the demand of producing smaller chip with high density elements on the chip.

In general, array packaging such as Ball Grid Array (BGA) packages provide a high density of interconnects relative to the surface area of the package. Typical BOA packages include a convoluted signal path, giving rise to high impedance and an inefficient thermal path which results in poor thermal dissipation performance. With increasing package density, the spreading of heat generated by the device is increasingly important.

Flip-chip technology is well known in the art for electrically connecting a die to a mounting substrate such as a printed wiring board. The active surface of the die is subject to numerous electrical couplings that are usually brought to the edge of the chip. Electrical connections are deposited as terminals on the active surface of a flip-chip. The bumps include solders and/or copper, gold that make mechanical connections and electrical couplings to a substrate. The solder bumps after RDL have bump high around 50-100 um. The chip is inverted onto a mounting substrate with the bumps aligned to bonding pads on the mounting substrate, as shown in FIG. 1. If the bumps are solder bumps, the solder bumps on the flip-chip are soldered to the bonding pads on the substrate. Solder joints are relatively inexpensive, but exhibit increased electrical resistance as well as cracks and voids over time due to fatigue from thermo-mechanical stresses. Further, the solder is typically a tin-lead alloy and lead-based materials are becoming far less popular due to environmental concerns over disposing of toxic materials and leaching of toxic materials into ground water supplies. Normally, the under fill materials are applied to reduce the thermal stress of CTE difference between silicon chip and substrate.

Furthermore, because conventional package technologies have to divide a dice on a wafer into respective dies and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dice). Generally, after completion of all assembling processes or packaging processes, individual semiconductor packages are separated from a wafer having a plurality of semiconductor dies. The wafer level package has extremely small dimensions combined with extremely good electrical properties.

U.S. Pat. No. 6,271,469 disclosed a package with RDL layer, 124 as shown in FIG. 2. The microelectronic package includes a microelectronic die 102 having an active surface. An encapsulation material 112 is disposed adjacent the microelectronic die side(s), wherein the encapsulation material includes at least one surface substantially planar to the microelectronic die active surface. A first dielectric material layer 118 may be disposed on at least a portion of the microelectronic die active surface and the encapsulation material surface. At least one conductive trace 124 is then disposed on the first dielectric material layer 118. The conductive trace(s) 124 is in electrical contact with the microelectronic die active surface. A second dielectric layer 126 and a third dielectric layer 136 are subsequently formed over the die. Via holes 132 are formed within the second dielectric layer 126 for coupling to the traces 124. Pads 134 are connected to the via holes 132 and solders 138 are located on the pads.

These conventional package structure and process design includes too many stacked dielectric layers over the die/substrate to form the build up layers, it not only requires the planar of active surface for RDL process and higher accuracy litho-photo machine to complete the packaging process but it is also easy to damage the chip surface during build up layers process. It is because there is lack of buffer layer between the silicon chip and solder ball, therefore, the scheme may suffer the poor yield and reliability concern.

Therefore, the present invention provides a structure with interconnecting structure for a flip chip scheme to overcome the aforementioned problem and also provide the better device performance.

### SUMMARY OF THE INVENTION

An object of the present invention is to provide a semiconductor device package (chip assembly) with a chip and a conductive trace that provides a low cost, high performance and high reliability package.

Another object of the present invention is to provide a convenient, cost-effective method for manufacturing a semiconductor device package (chip assembly).

In one aspect, an interconnecting structure for a semiconductor die assembly, comprising: a substrate with pre-formed wiring circuit formed therein; a die having contact pads on an active surface; an adhesive material formed over the substrate to adhere the die over the substrate, wherein the substrate includes a via through the substrate and the adhesive material; and conductive material refilled into the via to couple the contact pads of the die to the wiring circuit of the substrate.

The structure further comprises a core paste formed over the back side of die and the substrate or adhesive material and conductive balls coupled to the wiring circuits. A supporting base is formed over the core paste. A conductive layer me be formed over the core paste and/or back side of die. The conductive layer is formed by laminated copper foil, sputtering, E-plating Cu/Ni/Au.

Alternatively, an encapsulation is provided with slop structure over the die and the substrate or the adhesive material, and conductive balls coupled to the wiring circuits. The angle of the slop structure from the horizontal surface is abound 30-60 degrees. The encapsulated includes liquid compound or molding compound.

The present invention discloses a method of forming an interconnecting structure for a semiconductor die assembly, comprising:
providing forming a substrate with a wiring circuit;
forming an adhesion material on the substrate; or it may be formed on the die surface (silicon wafer surface)
attaching a die onto the adhesion material with flip die configuration by a fine alignment pick and place machine;
forming a core paste from back side of the die and filling space of die;
forming via within the substrate to open contact pads; it may be pre-formed in substrate process.
forming seed metal layer on the contact pads by PVD or CVD;
forming the photo-resistor over the substrate/die and opening via area;
performing E-plating process to form conductive material to refill into the via, thereby forming the inter-connecting to couple the contact pads of the die and wiring circuit of substrate.

The method further comprises curing the adhesive material after the adhesive material is formed; cleaning the contact pads after the step of opening by dry or wet; and striping the PR and etching back the seed metal layer after forming the interconnecting structure. In one case, the PR may be formed to protect the metal land of solder ball before PVD if there is no Au on the top of metal land of solder ball.

The seed metal layer includes Ti/Cu, Cu/Au, Cu/Ni/Au or Sn/Ag/Cu.

### BRIEF DESCRIPTION OF THE DRAWINGS

FIG. 1 is cross-sectional views showing a semiconductor chip assembly in accordance with prior art.

FIG. 2 is cross-sectional views showing a semiconductor chip assembly in accordance with prior art.

FIG. 3 illustrates a cross section view showing semiconductor chip assembly in accordance with embodiment of the present invention.

FIG. 4 illustrates a cross section view showing semiconductor chip assembly in accordance with embodiment of the present invention.

FIG. 5 illustrates a cross section view showing semiconductor chip assembly in accordance with further embodiment of the present invention.

FIG. 6 illustrates a cross section view showing semiconductor chip assembly in accordance with embodiment of the present invention.

FIGS. 7-10 illustrate cross section views showing the process in accordance with embodiment of the present invention.

FIG. 11 illustrates a cross section view showing interconnection structure in accordance with embodiment of the present invention.

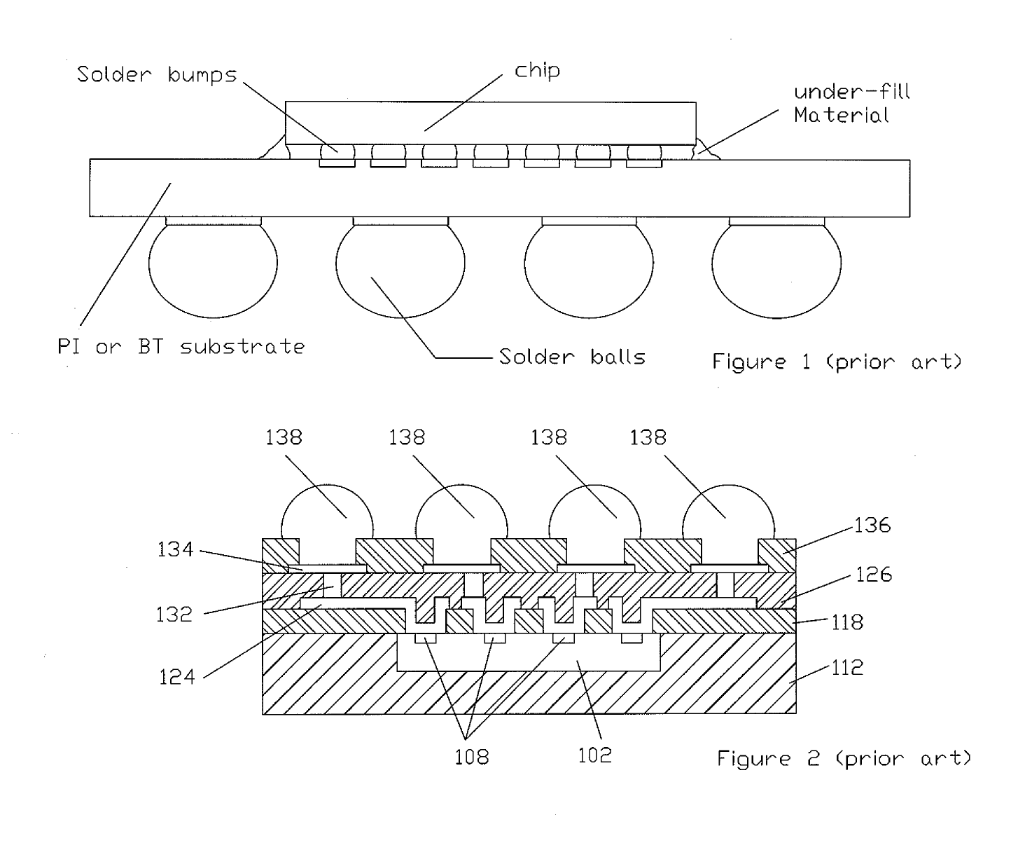

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying claims.

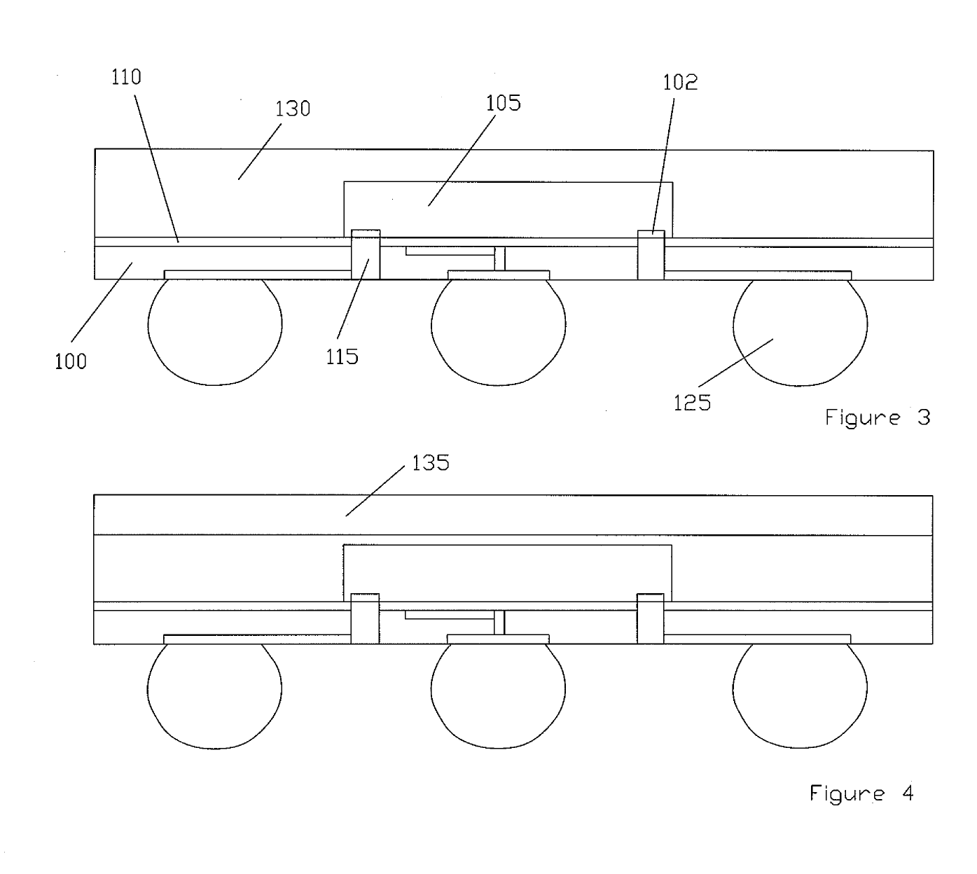

The present invention discloses a semiconductor device package structure. The present invention provide a semiconductor chip assembly which includes chip, conductive trace and metal inter-connecting as shown in FIG. 3.

FIG. 3 is cross-sectional view of a substrate 100. The substrate 100 could be a metal, glass, ceramic, plastic, PCB or PI. The thickness of the substrate 100 is around 40-70 micron-meters. It could be a single or multi-layer (wiring circuit) substrate. A chip 105 is adhesion on the surface by an adhesive material 110 with elastic properties to absorb the stress generated by thermal. The adhesive materials may be only cover the chip size area. Interconnecting structures 115 are refilled in the via-holes formed within the substrate 100 by laser drill. The interconnecting structures 115 are coupled to the contact pads 102 of the chip 105. The contact pads 102 are Al, copper pads or other metal pads and are formed after RDL in the silicon wafer. Traces 120 are configured on the lower or upper surface of the substrate 100 and coupled to the interconnecting structures 115. Conductive balls 125 are coupled to the ends of the traces 120.

In FIG. 3, conductive trace (routing line) 120 is formed under (inside) of the substrate. For example, the conductive trace 120 composed of gold, copper, copper-nickel or the like. The trace 120 is formed by an electroplating, plating or etching method. The copper electroplating operation continues until the copper layer has the desired thickness. Conductive trace 120 extends out of the area for receiving chip. The core paste 130 encapsulated the die 105 and over the substrate 100 or the adhesive material 110. It can be formed by resin, compound, silicon rubber or epoxy.

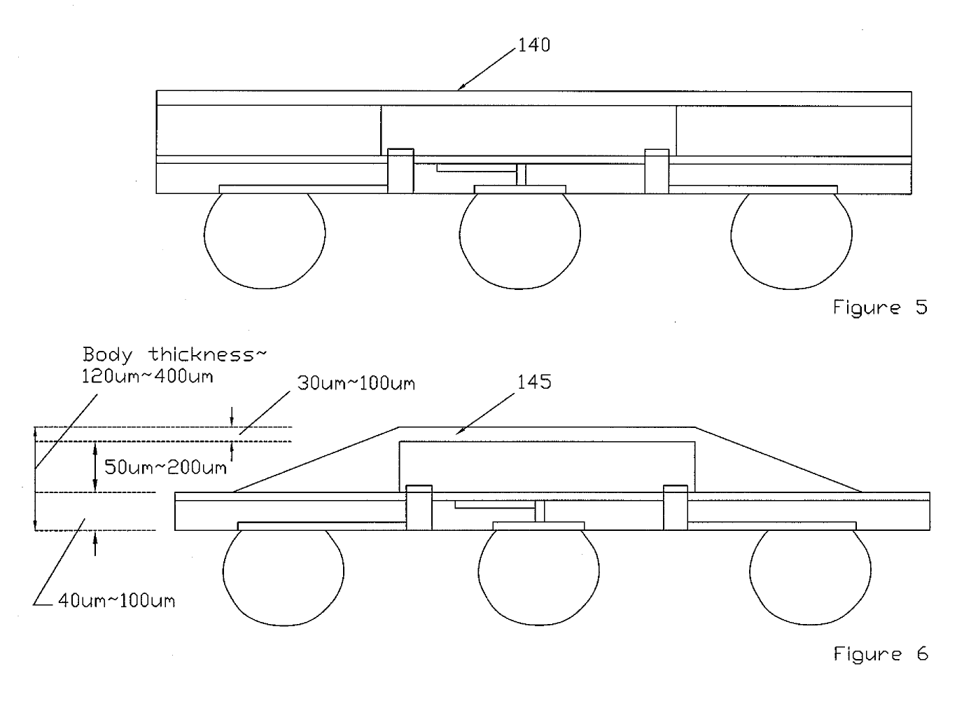

In FIG. 4 shows alternative embodiment of the present invention. A supporting base 135 is attached on the core paste 130 to offer rigid supporting for the package. Alternatively, a conductive layer 140 is coated or laminated over the core paste 130 to act as the heat sink. The layer 140 can be formed by laminating copper foil (adhesive by silver paste), sputtering, E-plating the Cu/Ni/Au, as shown in FIG. 5.

Please refer to FIG. 6, the molding encapsulate 145 is formed by liquid compound or molding compound to replace the core paste. The height of the die is around 50-200 micron meters, the dimension from the top of the die to the encapsulate 145 is around 30-100 micron meters. The thickness of the substrate adding the adhesive material is around 40-100 micron meters. Therefore, the body thickness of the device is around 120-400 micron meters. It should be noted that the encapsulate 145 includes “slope-roof.” The angle Θ of the slope structure 150 is around 30-60 degrees, and it may provide better thermal dissipation scheme than conventional.

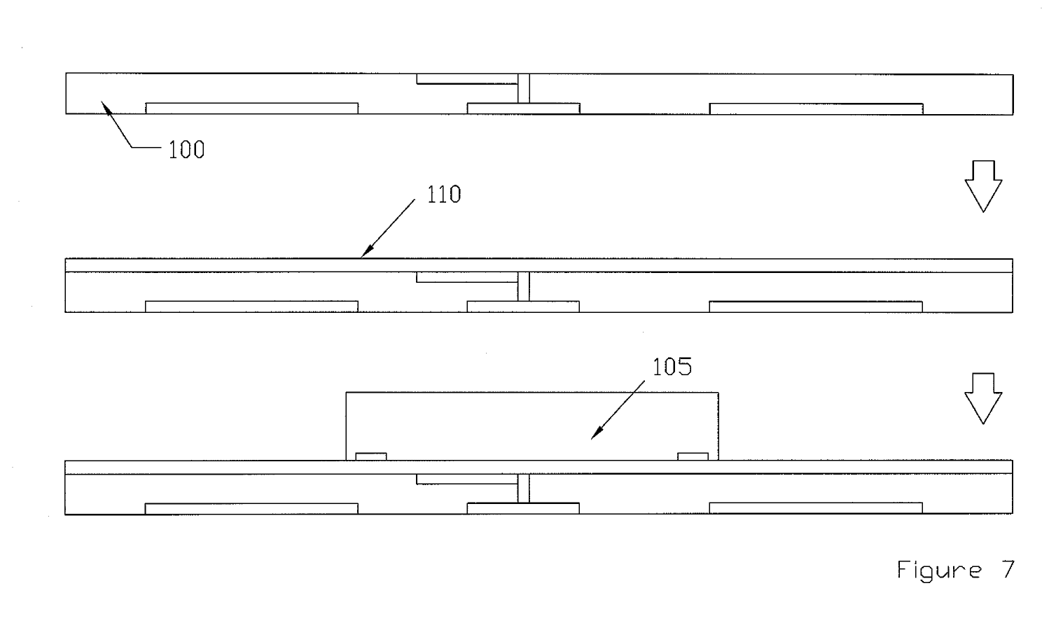

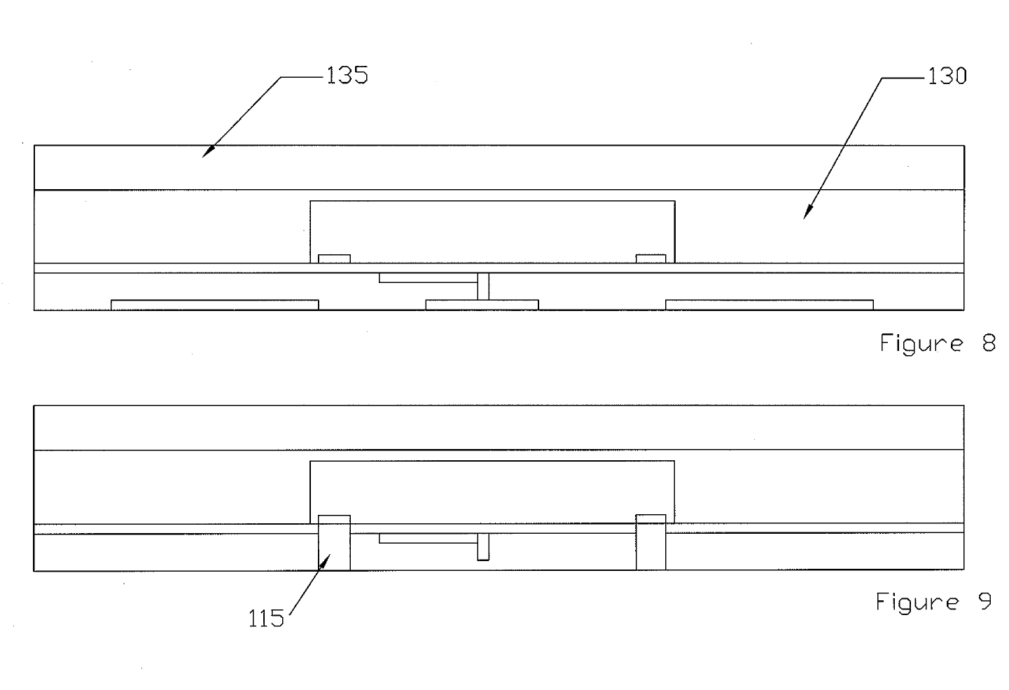

Turning to FIG. 7, a substrate (round or square shape) 100 with wiring circuits inside is prepared. The adhesive film 110 (preferably elastic properties to absorb the thermal stress due to CTE mis-match between silicon chip and substrate) is coated on the substrate, followed by pre-curing the film 110. The die 105 is nest placed on the (PI) substrate 100 by fine alignment machine, followed by final curing. The next step is to print or mold the core paste 130 (resin, compound, silicone rubber, etc.) from the back-site of dice 105. A panel bonding is used to bond the “Base” 135 on the back site (the step is optional), then curing to form the “Panel wafer,” as shown in FIG. 8. The next step is by employing the laser drill to “Open” the via (it may be open the via in substrate process before bonding the die), and forming the seed metal layer, followed by using the PR to form the Via-hole and area to connect the wiring circuit of substrate. E-plating is then used and after the PR strip, and etching the seed metal layer, thereby forming the inter-connecting structure 115. It should be noted that pads can be formed by Al bonding pads or metal pads after RDL in silicon wafer form, and the area of via-hole in not the area for forming ball, referring to FIGS. 8 and 9.

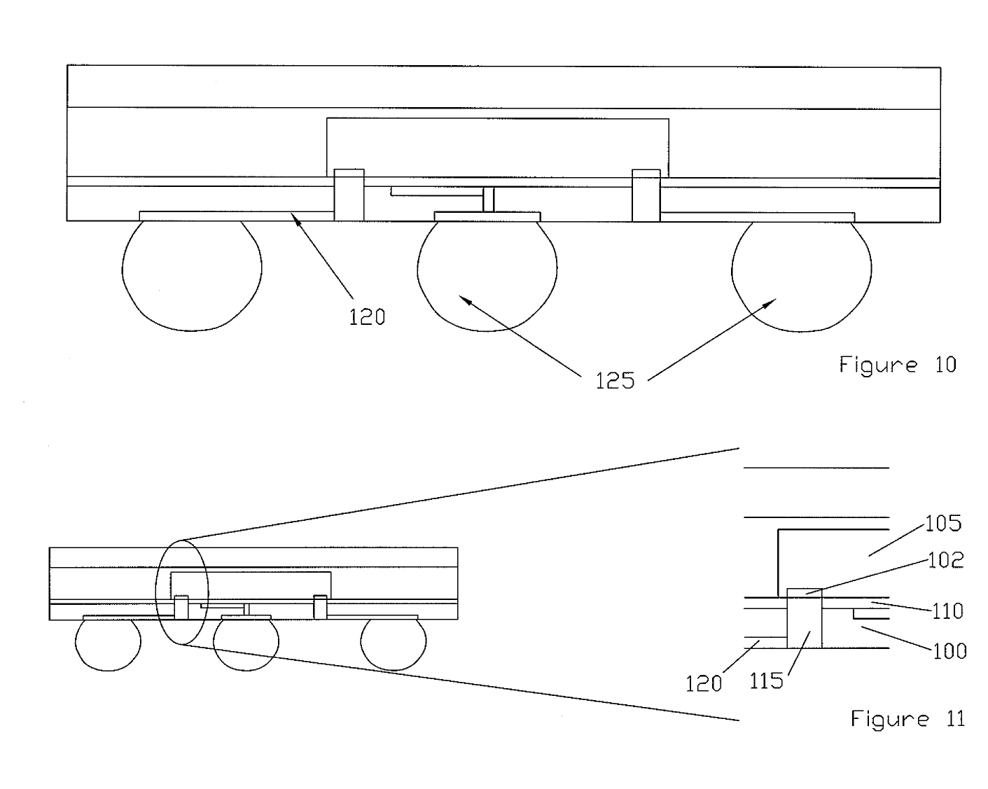

Next, the solder ball placement and IR re-flow steps are performed to form the final terminal, as shown in FIG. 10. After that, panel level final testing is introduced and cutting the (PI) substrate and core paste to singulate “panel wafer” into the individual packages.

FIG. 11 illustrates the interconnecting structure of the present invention. The structure of Inter-connecting of IC Package comprises a die 105 with metal contact pads 102 on the active surface. An adhesive material 110 is at the lower of the die 105. A substrate 100 with pre-formed wiring circuit 120 is provided to carry the die 105 and via-holes 115 is formed within the substrate 100 and said the adhesive material 110 with conductive materials 115 to couple the metal contact pads 102 of the die 105 to wiring circuit 120 of the substrate.

The present invention offers a simpler process than conventional methods. The present invention does not need RDL process in Panel wafer level (RDL means “wiring circuit” has been pre-made in substrate process to avoid the chip surface damaged during RDL process on the chip surface), and no alignment tools are necessary—the alignment pattern has been made on the surface of substrate during wiring circuit process, the die (active side) is attached on the elastic adhesive layers of substrate (No under-fill needed). The PI substrate is provided with wiring circuit by using large panel size. The present invention employs simple laminated dry PR instead of wet PR coating process to form the conductive material into via area. The dice can be packaged inside during process, only open the Pads, the active surface side has been protected. The scheme is low cost but high yield process and the dimension of the package structure is super-thin (No solder bump high need and silicon wafer is easy to be lapped as thinner as possible without solder bump high impact during process).

The present invention also provides better reliability structure by employing elastic adhesive layer as buffer layer to releasing the stress, filing metal (Cu or Sn) to full cover the Via for strong mechanical, it shows no thermal stress impact from the PI substrate in Z direction; it is difference once compare with current build up layer process. The CTE between PI substrate and PCB mother board is identical, thermal issue is removed, thus, thermal management is easy than ever.

The aforementioned structure comprises LGA (terminal pads in the peripheral of package) type package and BGA (Ball Grid Array) type.

Although preferred embodiments of the present invention have been described, it will be understood by those skilled in the art that the present invention should not be limited to the described preferred embodiment. Rather, various changes and modifications can be made within the spirit and scope of the present invention, as defined by the following claims.

Having described the invention, the following is claimed:

1. An interconnecting structure for a semiconductor die assembly, comprising:
a substrate with pre-formed wiring circuit formed therein;
a die having contact pads on an active surface;
an adhesive material formed over said substrate to adhere said die over said substrate, wherein said substrate includes a via through said substrate and said adhesive material; and
conductive material refilled into said via to couple said contact pads of said die to said wiring circuit of said substrate.

2. The structure of claim 1, further comprising a core paste formed over said die and said adhesive material and conductive balls coupled to said wiring circuits.

3. The structure of claim 2, further comprising a supporting base formed over said core paste.

4. The structure of claim 2, further comprising a conductive layer formed over said core paste.

5. The structure of claim 4, wherein said conductive layer is formed by laminated copper foil, sputtering, E-plating Cu/Ni/Au.

6. The structure of claim 1, further comprising a encapsulate with slop structure over said die and said adhesive material, and conductive balls coupled to said wiring circuits.

7. The structure of claim 6, wherein the angle of said slop structure from the horizontal surface is abound 30-60 degrees.

8. The structure of claim 6, wherein said encapsulate includes liquid compound or molding compound.

9. A method of forming an interconnecting structure for a semiconductor die assembly, comprising:
providing forming a substrate with a wiring circuit;
forming an adhesion material on said substrate;
attaching a die onto said adhesion material with flip die configuration by a fine alignment pick and place machine;
forming a core paste from back side of said die and filling space of die;
forming via within said substrate to open contact pads;
forming seed metal layer on said contact pads by PVD or CVD;
forming the photo-resistor over said die and opening via area;
performing E-plating process to form conductive material to refill into said via, thereby forming said inter-connecting to couple the contact pads of said die.

10. The method of claim 9, further comprising curing said adhesive material after said adhesive material is formed.

11. The method of claim 9, further comprising cleaning said contact pads after the step of opening by dry or wet.

12. The method of claim 9, wherein said seed metal layer includes Ti/Cu, Cu/Au, Cu/Ni/Au or Sn/Ag/Cu.

13. The method of claim 9, further comprising striping said PR and etching back said seed metal layer after forming said interconnecting structure.
